(19) United States
(12) Patent Application Publication
(10) Pub. No.: US 2018/0301433 A1
(43) Pub. Date: Oct. 18, 2018

(54) EMISSIVE LED DISPLAY DEVICE MANUFACTURING METHOD

(71) Applicant: Commissariat à l'Énergie Atomique et aux Énergies Alternatives, Paris (FR)

(72) Inventors: Ivan-Christophe Robin, Grenoble (FR); Jean Berthier, Meylan (FR); Séverine Cheramy, Claix (FR); Léa Di Cioccio, Saint Ismier (FR)

(73) Assignee: Commissariat à l'Énergie Atomique et aux Énergies Alternatives, Paris (FR)

(21) Appl. No.: 15/949,184

(22) Filed: Apr. 10, 2018

(30) Foreign Application Priority Data
Apr. 14, 2017 (FR) 17/53279

(51) Int. Cl. H01L 23/00; H01L 33/62; H01L 25/065; H01L 33/44; H01L 21/683

(52) U.S. Cl. CPC H01L 24/80; H01L 24/95; H01L 33/62; H01L 25/0655; H01L 33/32; H01L 21/6835; H01L 2224/80895; H01L 2224/80143; H01L 33/44

(57) ABSTRACT

A method of manufacturing an emissive LED display device, including the steps of forming a plurality of chips, each including at least one LED and, on a connection surface, a plurality of hydrophilic electric connection areas and a hydrophobic area; forming a transfer substrate including, for each chip, a plurality of hydrophilic electric connection areas and a hydrophobic area; arranging a drop of a liquid on each electric connection area of the transfer substrate and/or of each chip; and affixing the chips to the transfer substrate by direct bonding, using the capillary restoring force of the drops to align the electric connection areas of the chips with the electric connection areas of the transfer substrate.

This application claims the priority benefit of French patent application number 17/53279, the content of which is hereby incorporated by reference in its entirety to the maximum extent allowable by law.

### BACKGROUND

The present application concerns the forming of an emissive image display device comprising light-emitting diodes (LEDs), for example, a display screen for a television, computer, smart phone, tablet, etc.

### DISCUSSION OF THE RELATED ART

A method of manufacturing an image display device comprising a plurality of elementary electronic microchips arranged in an array on a same transfer substrate has already been provided in French patent application FR3044467 (filing Nr. 1561421) filed on Nov. 26, 2015. According to this method, the microchips and the transfer substrate are manufactured separately. Each microchip comprises a stack of a LED and of a circuit for controlling the LED. The control circuit comprises a connection surface opposite to the LED, comprising a plurality of electric connection areas intended to be connected to the transfer substrate for the microchip control. The transfer substrate comprises a connection surface comprising, for each microchip, a plurality of electric connection areas intended to be respectively connected to the electric connection areas of the microchip. The chips are then placed on the transfer substrate, with their connection surfaces facing the connection surface of the transfer substrate, and affixed to the transfer substrate to connect the electric connection areas of each microchip to the corresponding electric connection areas of the transfer substrate.

It would be desirable to be able to at least partly improve certain aspects of this method.

In particular, due to the relatively small dimensions of the microchips, and given that each microchip comprises a plurality of separate electric connection areas, the alignment of the electric connection areas of the microchips with the corresponding electric connection areas of the transfer substrate is relatively difficult to achieve. It would be desirable to ease the implementation of such an alignment and/or to improve the obtained alignment accuracy.

### SUMMARY

Thus, an embodiment provides a method of manufacturing an emissive LED display device, comprising the steps of:

a) forming a plurality of chips, each comprising at least one LED and, on a connection surface of the chip, a plurality of hydrophilic electric connection areas and a hydrophobic area, each electric connection area of the chip being surrounded and separated from the other electric connection areas of the chip by the hydrophobic area;

b) forming a transfer substrate comprising, for each chip, on a connection surface of the transfer substrate, a plurality of hydrophilic electric connection areas intended to be respectively connected to the electric connection areas of the chip, and a hydrophobic area, each electric connection area of the transfer substrate being surrounded and separated from the other electric connection areas of the transfer substrate by the hydrophobic area;

c) arranging a drop of a liquid on each electric connection area of the transfer substrate and/or on each electric connection area of each chip; and

d) affixing the chips to the transfer substrate by direct bonding, to electrically connect the electric connection areas of each chip to the corresponding electric connection areas of the transfer substrate, using the capillary restoring force of the drops to align the electric connection areas of the chips with the corresponding electric connection areas of the transfer substrate.

According to an embodiment, the electric connection areas of the chips and of the transfer substrate are made of metal, and the hydrophobic areas of the chips and of the transfer substrate are made of a hydrophobic polymer.

According to an embodiment, the electric connection areas of the chips are made of a material forming a drop contact angle smaller than 10° with the liquid, and the hydrophobic areas are made of a material forming a drop contact angle greater than 20° with the liquid.

According to an embodiment:

in each chip, the connection surface of the chip is planar, that is, the electric connection areas of the chip are flush with the external surface of the hydrophobic area; and/or

the connection surface of the transfer substrate is planar, that is, the electric connection areas of the transfer substrate are flush with the external surface of the hydrophobic area.

According to an embodiment:

in each chip, the electric connection areas of the chip form raised areas protruding from the connection surface of the chip; and/or

the electric connection areas of the transfer substrate form raised areas protruding from the connection surface of the transfer substrate.

According to an embodiment:

at the end of step a), the chips are arranged on a support substrate with a pitch between chips smaller than the pitch between chips of the final display device; and

at step d), a plurality of chips are selectively separated from the support substrate at the pitch of the final display device and affixed to the transfer substrate at this same pitch.

According to an embodiment, the selective separation of the chips is formed by means of a local laser beam projected from the surface of the support substrate opposite to the chips.

According to an embodiment, the support substrate comprises one or a plurality of through openings opposite each chip, the selective separation of the chips being performed via the openings.

According to an embodiment:

at the end of step a), the chips are only laid, with no bonding, on the support substrate; and

at step d), the transfer substrate is brought above the chips, with its connection surface facing the connection surfaces of the chips, and laid on the chips to simultaneously sample a plurality of chips at the pitch of the final display device.

According to an embodiment, the support substrate comprises cavities having the chips arranged therein so that the chips are laterally held by the cavity walls.

According to an embodiment, the bottom of each cavity of the support substrate is non-planar.

According to an embodiment, each chip comprises a stack of a LED and of an active circuit for controlling the LED.

Another embodiment provides an emissive LED display device formed by a method such as defined hereabove.

The foregoing and other features and advantages will be discussed in detail in the following non-limiting description of specific embodiments in connection with the accompanying drawings.

### BRIEF DESCRIPTION OF THE DRAWINGS

FIG. 1 is a cross-section view schematically and partially illustrating a step of transferring a microchip onto a transfer substrate, according to an example of a method of manufacturing an emissive LED display device;

FIG. 2 is a cross-section view schematically and partially illustrating a step of transferring a microchip onto a transfer substrate, according to an example of an embodiment of a method of manufacturing an emissive LED display device;

FIG. 3 is a cross-section view schematically and partially illustrating a step of transferring a microchip onto a transfer substrate, according to another embodiment of a method of manufacturing an emissive LED display device;

FIGS. 4A, 4B, and 4C are cross-section views illustrating steps of an embodiment of a method of manufacturing an emissive LED display device;

FIG. 5 is a cross-section view illustrating an alternative embodiment of the method of FIGS. 4A to 4C;

FIGS. 6A, 6B, 6C, and 6D are cross-section views illustrating steps of another embodiment of a method of manufacturing an emissive LED display device;

FIGS. 7A, 7B, 7C, and 7D are cross-section views illustrating steps of another embodiment of a method of manufacturing an emissive LED display device; and

FIG. 8 is a cross-section view illustrating an alternative embodiment of the method of FIGS. 7A to 7D.

### DETAILED DESCRIPTION

The same elements have been designated with the same reference numerals in the various drawings and, further, the various drawings are not to scale. For clarity, only those steps and elements which are useful to the understanding of the described embodiments have been shown and are detailed. In particular, the manufacturing of the elementary microchips and of the transfer substrate of the described display devices has not been detailed, the manufacturing of these elements being within the abilities of those skilled in the art based on the teachings of the present description. As an example, the elementary microchips and the transfer substrate may be manufacturing according to methods identical or similar to those described in the above-mentioned French patent application FR3044467, which is herein incorporated by reference as authorized by law. In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings, it being understood that, in practice, the described devices may be oriented differently. The terms “approximately”, “substantially”, and “in the order of” are used herein to designate a tolerance of plus or minus 10%, preferably of plus or minus 5%, of the value in question.

FIG. 1 is a cross-section view schematically and partially illustrating a step of transferring a microchip 100 onto a transfer substrate 150, according to an example of a method of manufacturing an emissive LED display device.

FIG. 1 more particularly shows microchip 100 and transfer substrate 150 before the actual step of affixing the microchip onto the transfer substrate.

In particular, a display device may comprise a plurality of identical or similar elementary chips 100 assembled on a same transfer substrate in an array of rows and columns, the chips being connected to elements of electric connection of the substrate for the control thereof, and each microchip for example corresponding to a pixel of the display device.

Microchip 100 comprises, in an upper portion, an inorganic semiconductor LED 110 and, in a lower portion forming one piece with the upper portion, an active control circuit 120 based on single-crystal silicon, capable of controlling the emission of light by the LED.

LED 110 comprises at least one homojunction or one heterojunction, for example, a PN junction formed of a stack of an upper N-type semiconductor layer 112 and of a lower P-type semiconductor layer 114, and two electric contacts 116 and 118 (respectively in contact with layer 112 and with layer 114 in the shown example) to inject an electric current through the stack, in order to generate light. As an example, LED 110 is a gallium nitride LED or is based on any other III-V semiconductor capable of forming a LED.

Control circuit 120 is formed inside and on top of a single-crystal silicon block 121 and comprises electronic components, and particularly one or a plurality of transistors and at least one capacitive element for holding a bias signal, for the individual control of LED 110. The upper surface of control circuit 120 is mechanically and electrically in contact with LED 110. The lower surface of circuit 120, defining a connection surface of the microchip, comprises a plurality of electric connection areas intended to be connected to corresponding connection areas of transfer substrate 150 for the control of the microchip. In the shown example, the lower surface of circuit 120 comprises four electric connection areas 125, 126, 127, and 128. Areas 125 and 126 are intended to respectively receive a low power supply potential (for example, the ground) Vn and a high power supply potential (that is, higher than the low power supply potential) Vp of the microchip. Areas 127 and 128 are intended to receive microchip control signals. More particularly, area 127 is intended to receive a microchip selection signal Vsel, and area 128 is intended to receive a signal Vdata for adjusting the luminosity level of the microchip. Connection areas 125, 126, 127, and 128 are for example made of metal, for example, of copper. In this example, control circuit 120 comprises two MOS transistors 122 and 123 and one capacitive element 124, for example, a capacitor. Transistor 122, for example, a P-channel transistor, has a first conduction node (source or drain) connected to the connection area 126 (Vp) of the microchip, a second conduction node (drain or source) connected to anode contact terminal 118 of LED 110, and a control node (gate) connected to an intermediate node al of circuit 120. Capacitive element 124 has a first electrode connected to node al and a second electrode connected to the microchip connection area 126 (Vp). Transistor 123, for example, an N-channel transistor, has a first conduction node connected to connection area 128 (Vdata) of the microchip, a second conduction node connected to node al, and a control node connected to connection area 127 (Vsel) of the microchip. Microchip 100 further comprises an insulated conductive via 129 connecting electric connection range 125 (Vn) of the microchip to cathode contact terminal 116 of LED 110.

Elementary microchip 100 operates as follows during a phase of updating the luminosity level of the pixel. Transistor 123 is turned on (made conductive) by the application of an adapted control signal to terminal 127 (Vsel). Capacitive element 124 then charges to a voltage level which is a function of the adjustment signal applied to terminal 126 (Vdata) of the microchip. The level of adjustment signal Vdata sets the potential of node al, and accordingly the intensity of the current injected into the LED by transistor 122, and thus the light intensity emitted by the LED. Transistor 123 can then be turned back off. Node al then remains at a potential substantially equal to potential Vdata. Thus, the current injected into the LED remains substantially constant after the turning back off of transistor 123, and this, until the next update of the potential of node al.

Transfer substrate 150 for example comprises a support plate or sheet 151 made of an insulating material, having electric connection elements, for example, conductive tracks and areas, arranged thereon. Transfer substrate 150 is for example a passive substrate, that is, it only comprises electric connection elements for conveying the microchip control and power supply signals. Transfer substrate 150 comprises a connection surface, its upper surface in the shown example, intended to receive microchips 100. For each microchip of the display device, transfer substrate 150 comprises, on its connection surface, a plurality of electric connection areas (one per electric connection area of the microchip) intended to be respectively connected to the electric connection areas of the microchip. Thus, in this example, for each microchip 100 of the display device, transfer substrate 150 comprises four electric connection areas 155, 156, 157, and 158 intended to be respectively connected to electric connection areas 125, 126, 127, and 128 of microchip 100, to convey control signals Vn, Vp, Vsel, and Vdata of the microchip. Electric connection areas 155, 156, 157, and 158 of the transfer substrate are for example made of the same conductive material as electric connection areas 125, 126, 127, and 128 of the microchips, for example, copper.

During the transfer of microchip 100 onto transfer substrate 150, the connection surface of the microchip is placed in contact with the connection surface of the transfer substrate to electrically connect electric connection areas 125, 126, 127, and 128 of the microchip respectively to the corresponding electric connection areas 155, 156, 157, and 158 of the transfer substrate. The affixing of microchip 100 to the transfer substrate is performed by direct bonding, that is, with no added adhesive or solder material at the interface between the microchip and the substrate, for example, at ambient temperature and pressure. To achieve this, the electric connection areas of the microchip and of the transfer substrate may have been previously prepared to obtain a sufficient evenness, for example, a roughness lower than 1 nm, to achieve a direct bonding of areas 125, respectively 126, respectively 127, respectively 128, onto areas 155, respectively 156, respectively 157, respectively 158. An anneal may optionally be provided after the bonding, for example, at a temperature in the range from 150 to 250° C., to increase the strength of the bonding.

As indicated hereabove, a difficulty of such a method is the alignment of the electric connection areas of the microchip with the corresponding electric connection areas of the transfer substrate to obtain a good electric connection between the microchip and the transfer substrate.

Indeed, the microchips for example have, in top view, a maximum dimension smaller than or equal to 100 μm, for example, smaller than or equal to 50 μm, for example, in the order of 10 μm. Each microchip comprising a plurality of electric connection areas (four in the example of FIG. 1), the alignment of the microchips should be very accurate, for example, with an accuracy better than to within than 1 μm.

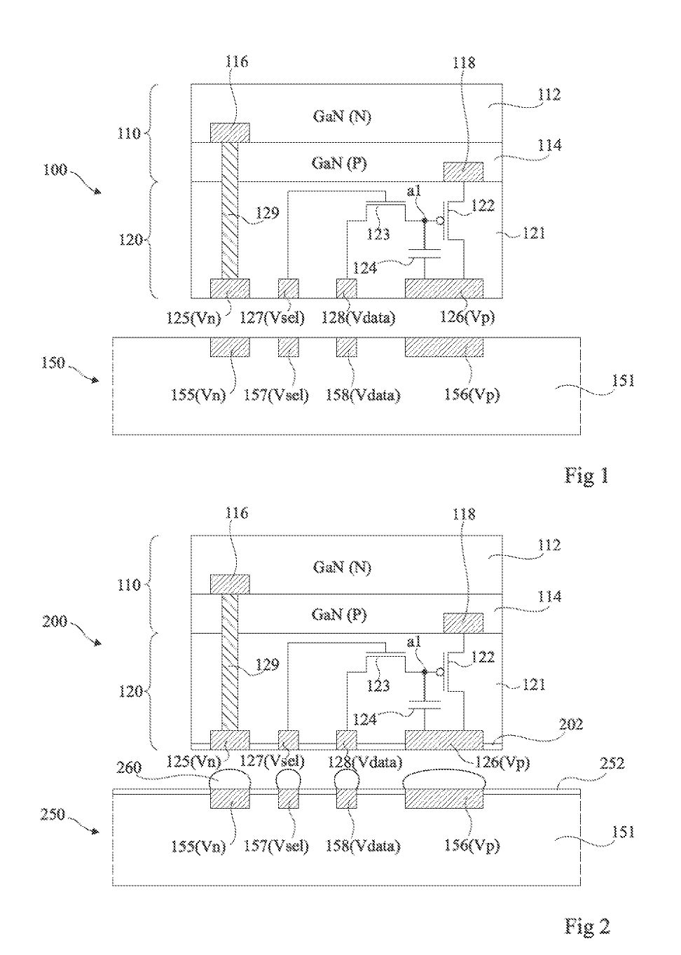

FIG. 2 is a cross-section view schematically and partially illustrating a step of transferring a microchip 200 onto a transfer substrate 250, according to an example of an embodiment of a method of manufacturing an emissive LED display device. FIG. 2 more particularly shows microchip 200 and transfer substrate 250 before the actual step of affixing the microchip onto the transfer substrate.

Microchip 200 and transfer substrate 250 of FIG. 2 comprise elements common with microchip 100 and transfer substrate 150 of FIG. 1. Hereafter, only the differences between the embodiment of FIG. 2 and the example of FIG. 1 will be detailed.

Microchip 200 of FIG. 2 differs from microchip 100 of FIG. 1 mainly in that it comprises, on the side of its connection surface, a hydrophobic layer 202 made of an electrically-insulating material, laterally surrounding electric connection areas 125, 126, 127, and 128 of the microchip. In the shown example, hydrophobic layer 202 extends over substantially the entire lower surface of the microchip which is not occupied by electric connection areas 125, 126, 127, and 128. As an example, in front view, each of electric connection areas 125, 126, 127, and 128 of the microchip is totally surrounded with hydrophobic layer 202 and separated from the other electric connection areas by hydrophobic layer 202. Electric connection areas 125, 126, 127, and 128 are provided to be hydrophilic.

Thus, in the example of FIG. 2, the connection surface of the microchip comprises a plurality of hydrophilic areas, corresponding to electric connection areas 125, 126, 127, and 128, each laterally surrounded and separated from the other hydrophilic areas by a hydrophobic area (layer 202).

In the example of FIG. 2, the lower surface or connection surface of microchip 200 is substantially planar, that is, electric connection areas 125, 126, 127, and 128 of the microchip are flush with the lower surface of hydrophobic layer 202. As an example, electric connection areas 125, 126, 127, and 128 are formed according to a damascene-type method, comprising a step of depositing the hydrophobic layer over the entire lower surface of the microchip, followed by a step of etching cavities intended to receive electric connection areas 125, 126, 127, and 128 on the lower surface side of the microchip, followed by a step of filling the cavities with a conductive material to form the electric connection areas, followed by a step of chem.-mech. polishing to planarize the lower surface of the chip to place the lower surfaces of electric connection areas 125, 126, 127, and 128 at a same level as the lower surface of hydrophobic layer 202.

Terms hydrophobic and hydrophilic here mean that the material of layer 202 has a relatively low wettability and that the material of the electric connection areas has a relatively high wettability.

Generally, the wettablity of a material may be characterized by the contact angle of a liquid drop on a horizontal surface of the material at the atmospheric pressure, that is, the angle between the tangent to the drop and the surface of the material at the solid/liquid/gas triple contact point. The smaller the contact angle, the higher the wettability of the material.

It is here desired to obtain a high wettability difference between the hydrophobic area and the hydrophilic areas of the microchip connection surface, to allow the confinement of a drop of a liquid on each electric connection area of the microchip, to ease the alignment of the electric connection areas of the microchip with the corresponding electric connection areas of the transfer substrate, as will be described in further detail hereafter.

As an example, hydrophilic means that the contact angle of a water drop on the material of electric connection areas 125, 126, 127, and 128 is smaller than 10°, and preferably smaller than 5°, and hydrophobic means that the contact angle of a water drop on the material of layer 202 is greater than 20°, preferably greater than 60°, preferably greater than 90°. In the example of FIG. 2, the drop contact angle difference between the hydrophilic material and the hydrophobic material is preferably greater than 90°, preferably greater than 110°.

Hydrophobic layer 202 is for example made of a hydrophobic material, for example, polymer Bosch C4F8, polytetrafluoroethylene (TEFLON), an anti-adhesive polymer of the type commercialized by Daikin under trade name OPTOOL DSX, or of any other adapted hydrophobic material.

Similarly, transfer substrate 250 of FIG. 2 differs from transfer substrate 150 of FIG. 1 mainly in that it comprises, on its connection surface side, a hydrophobic layer 252 made of an electrically-insulating material, laterally surrounding electric connection areas 155, 156, 157, and 158 of the substrate. In the shown example, hydrophobic layer 252 extends over substantially the entire upper surface of the transfer substrate which is not occupied by electric connection areas 155, 156, 157, and 158. As an example, in front view, each of electric connection areas 155, 156, 157, and 158 of the transfer substrate is totally surrounded with hydrophobic layer 252 and separated from the other electric connection areas by hydrophobic layer 252. Electric connection areas 155, 156, 157, and 158 are provided to be hydrophilic.

In the example of FIG. 2, the upper surface or connection surface of transfer substrate 250 is substantially planar, that is, electric connection areas 155, 156, 157, and 158 of the transfer substrate are flush with the upper surface of hydrophobic layer 252. As an example, electric connection areas 155, 156, 157, and 158 are formed according to a damascene-type method after the deposition of the hydrophobic layer over the entire upper surface of the transfer substrate.

As for the microchip, it is here desired to obtain a high wettability difference between the hydrophobic area and the hydrophilic areas of the microchip connection surface, to allow the confinement of a drop of a liquid on each electric connection area of the microchip, to ease the alignment of the electric connection areas of the microchip with the corresponding electric connection areas of the transfer substrate

As an example, the contact angle of a water drop on the material of electric connection areas 155, 156, 157, and 158 is smaller than 10° and preferably smaller than 5°, and the contact angle of a water drop on the material of layer 252 is greater than 20°, preferably greater than 60°, preferably greater than 90°. The drop contact angle difference between the material of electric connection areas 155, 156, 157, and 158 and the material of layer 252 is preferably greater than 90°, for example, greater than 110°.

As an example, electric connection areas 155, 156, 157, and 158 of transfer substrate 250 are made of the same material as electric connection areas 125, 126, 127, and 128 of microchip 200, and hydrophobic layer 252 of transfer substrate 250 is made of the same material as hydrophobic layer 202 of microchip 200.

In the example of FIG. 2, it is provided, before the actual transfer of microchip 200 onto transfer substrate 250, to place a drop of a liquid 260, for example, water, on each electric connection area of the transfer substrate and/or on each electric connection area of the microchip.

In the shown example, the drops are only placed on the electric connection areas of the transfer substrate. For this purpose, the upper surface of the transfer substrate is for example plunged into a bath of liquid 260. As a variation, liquid 260 may be sprayed on the upper surface of the transfer substrate. Due to the hydrophilic/hydrophobic contrast between electric connection areas 155, 156, 157, and 158 of the substrate and hydrophobic layer 252, drops of liquid 260 are only confined on electric connection areas 155, 156, 157, and 158 of the transfer substrate, that is, four drops per microchip in the example of FIG. 2.

Microchip 200 is then placed on substrate 250, with its connection surface facing the connection surface of substrate 250. More particularly, electric connection areas 125, 126, 127, and 128 of the microchip are laid on the drops of liquid 260 topping the corresponding electric connection areas 155, 156, 157, and 158 of the transfer substrate.

During this step, the capillary restoring force exerted by the drops of liquid 260 on the hydrophilic surfaces, that is, on the electric connection areas, enables to accurately align the electric connection areas of the microchip with the corresponding electric connection areas of the transfer substrate.

It should be noted that the capillary restoring force exerted by each microdrop is proportional to the length of the periphery of the drop, or length of the air/solid/liquid triple contact line of the microdrop. Thus, the fact of providing one drop per electric connection area of the microchip enables to benefit from a higher alignment restoring force than if a single drop was provided for the alignment of the microchip.

Once the alignment of microchip 200 with the transfer substrate has been performed with the assistance of drops of liquid 260, microchip 200 is affixed to transfer substrate 250 by direct bonding of electric connection areas 125, 126, 127, and 128 of the microchip onto the corresponding electric connection areas 155, 156, 157, and 158 of the transfer substrate. For this purpose, a pressure may for example be applied to microchip 200 to drain off the drops of liquid 260, or liquid 260 may be evaporated, to place the connection surface of the microchip into contact with the connection surface of the transfer substrate, and thus obtain the direct bonding of electric connection areas 125, 126, 127, and 128 of the microchip to electric connection areas 155, 156, 157, and 158 of the transfer substrate. The electric connection areas of the microchip and of the transfer substrate may have been previously prepared to obtain a sufficient evenness to perform the direct bonding. An anneal may possibly be provided after the bonding, for example, at a temperature in the range from 150 to 250° C., to increase the bonding energy.

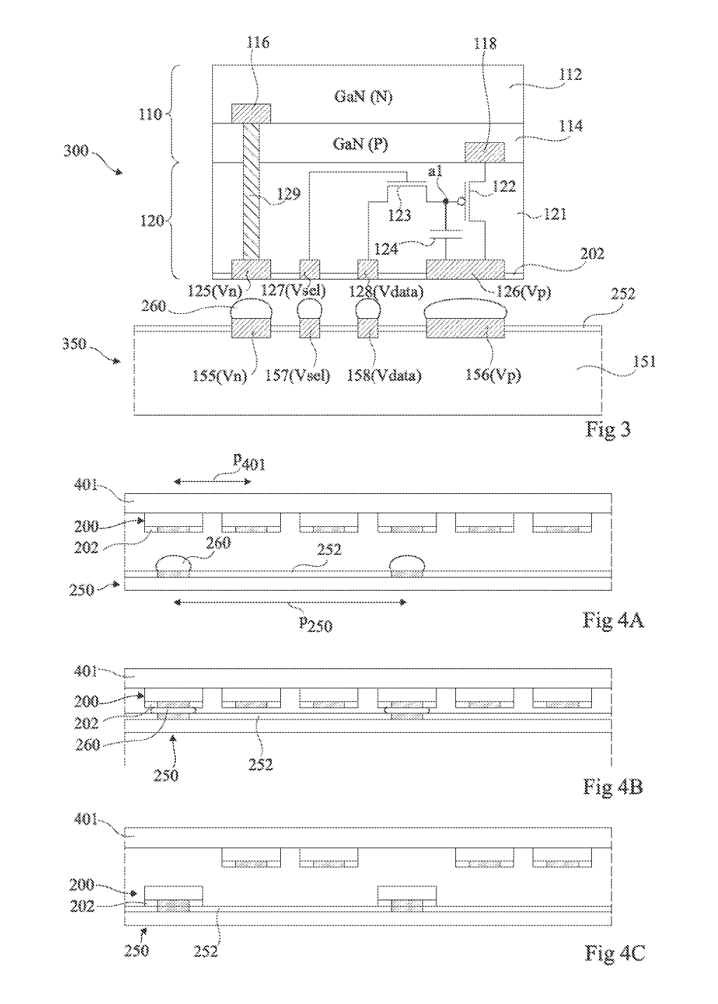

FIG. 3 is a cross-section view schematically and partially illustrating a step of transferring a microchip 300 onto a transfer substrate 350, according to an example of an embodiment of a method of manufacturing an emissive LED display device.

FIG. 3 more particularly shows microchip 300 and transfer substrate 350 before the actual step of affixing the microchip onto the transfer substrate.

Microchip 300 of FIG. 3 comprises elements common with microchip 200 of FIG. 2, and transfer substrate 350 of FIG. 3 comprises elements common with transfer substrate 250 of FIG. 2.

Hereafter, only the differences between the embodiment of FIG. 3 and the embodiment of FIG. 2 will be detailed.

Microchip 300 of FIG. 3 differs from microchip 200 of FIG. 2 mainly in that, in microchip 300, electric connection areas 125, 126, 127, and 128 form raised areas protruding from the lower surface of the chip. Thus, conversely to microchip 200 having a substantially planar connection surface, microchip 300 has a structured connection surface. More particularly, the raised areas formed by the electric connection areas of the microchip have a mesa or table shape, the upper surface of each raised area forming a sharp edge with the sides of the raised area.

Similarly, transfer substrate 350 of FIG. 3 differs from transfer substrate 250 of FIG. 2 mainly in that, in transfer substrate 350, electric connection areas 155, 156, 157, and 158 form raised areas protruding from the upper surface of the substrate. Thus, conversely to transfer substrate 250, which has a substantially planar connection surface, transfer substrate 350 has a structured connection surface. More particularly, the raised areas formed by the electric connection areas of the transfer substrate have a mesa or table shape, the upper surface of each raised area forming a sharp edge with the sides of the raised area.

An advantage of the variation of FIG. 3 is that it enables to benefit, in addition to the wettability difference between the electric connection areas and the hydrophobic area surrounding the electric connection areas, from an effect of anchoring of the drops of liquid 260 to the top of each raised area to maintain the drops confined on the electric connection areas.

As a variation, only the electric connection areas of the transfer substrate form raised areas, the connection surface of each microchip being substantially planar such as described in the example of FIG. 2. In another variation, only the electric connection areas of the microchip form raised areas, the connection surface of the transfer substrate being substantially planar as described in the example of FIG. 2.

FIGS. 4A, 4B, and 4C are cross-section views illustrating steps of an embodiment of a method of manufacturing an emissive LED display device.

FIG. 4A illustrates a step during which, after having separately formed microchips 200 on a support substrate 401 and transfer substrate 250, and after having arranged drops of liquid 260 on the electric connection areas of transfer substrate 250, microchips 200 are approximately positioned opposite the corresponding transfer areas of substrate 250, with the connection surfaces of the microchips facing the connection surface of substrate 250, while using support substrate 401 as a handle.

As an example, the method of manufacturing microchips 200 is a method of the type described in above-mentioned French patent application FR3044467, comprising:

forming an array of identical or similar elementary control circuits 120, inside and on top of a silicon substrate;

separately forming, on an adapted growth substrate, for example, made of sapphire, a corresponding array of identical or similar elementary LEDs 110;

transferring, onto each other, the array of control circuits 120 and LED array 110, the two arrays being solidly attached to each other, for example, by direct heterogeneous bonding;

removing the growth substrate of the LEDs and replacing it with a support substrate, corresponding to substrate 401 of FIG. 4A, affixed by so-called temporary bonding, having a lower bonding energy than the initial bond between the microchips and the LED growth substrate, to ease a subsequent microchip sampling step; and

individualizing each microchip 200 by etching around it a trench vertically extending from the connection surface of the microchip all the way to substrate 401, to obtain an array of individualized microchips affixed to support substrate 401 by their LEDs, as shown in FIG. 4A.

As a variation, the step of replacing the LED growth substrate with a different support substrate may be omitted, in which case substrate 401 of FIG. 4A is the LED growth substrate. In this case, the bonding between substrate 401 and LEDs 110 may possibly be weakened, by means of a laser beam projected through substrate 401 from its back side, that is, its surface opposite to microchips 200.

In another variation, the stack of the semiconductor layers forming the LEDs may be placed on the array of elementary control circuits 120 before the individualization of elementary LEDs 110. The LED growth substrate is then removed to allow the individualization of LEDs 110, after which support substrate 401 may be bonded to the surface of LEDs 110 opposite to control circuits 120.

For simplification, a single electric connection area per microchip has been shown in FIGS. 4A to 4C. In practice, as previously indicated, each microchip comprises a plurality of electric connection areas on its connection surface. Further, still to simplify the drawings, microchips 200 have not been detailed in FIGS. 4A to 4C and the following. Only hydrophobic layer 202 and the single electric connection area (shown as a hatched area, with no reference) are shown. Similarly, transfer substrate 250 has not been detailed in FIGS. 4A to 4C and the following. Only hydrophobic layer 252 and, for each microchip, an electric connection area (shown as a hatched area, with no reference) are shown.

The microchips 200 attached to support substrate 401 by their LEDs are brought opposite corresponding reception areas of transfer substrate 250, with their connection surfaces facing the connection surface of substrate 250, and laid on the drops of liquid 260 topping the electric connection areas of the transfer substrate.

During this step, the capillary restoring force exerted by the drops of liquid 260 on the hydrophilic electric connection areas enables to accurately align the electric connection areas of each microchip with the corresponding electric connection areas of the transfer substrate.

It should be noted that the fact of simultaneously placing a plurality of microchips 200 on substrate 250 enables to benefit from a higher capillary restoring force than if a single chip was placed, since the capillary restoring forces exerted by the drops associated with the different transferred microchips add to one another.

Microchips 200 are then affixed to transfer substrate 250 by direct bonding of the electric connection areas of the microchips onto the corresponding electric connection areas of the transfer substrate. For this purpose, a pressure may for example be applied to microchips 200 to drain off the drops of liquid 260, or liquid 260 may be evaporated, to obtain a direct bonding between the microchips and the transfer substrate.

Microchips 200 are then separated from support substrate 401, and the latter is removed.

In practice, pitch p401 of the microchips on substrate 401, for example, in the range from 10 to 50 μm, may be smaller than pitch p250 of the final device after the transfer onto substrate 250, for example, in the range from 15 μm to 1 mm, for example, in the range from 100 to 500 μm.

In the example described in relation with FIGS. 4A to 4C, as well as in the examples of the next drawings, pitch p250 of the microchips 200 on transfer substrate 250 is a multiple of pitch p401 of the microchips on support substrate 401. Thus, it is provided to only place part of microchips 200 of substrate 401 on substrate 250, at the pitch of transfer substrate 250 (that is, one chip out of n, with n=p250/p401), and then, if need be, to shift substrate 401 with the remaining microchips to place another part of microchips 200 of substrate 401 on substrate 250, and so on until all the microchips of the display device have been affixed to transfer substrate 250.

For each iteration, once the alignment of microchips 200 with the transfer substrate has been performed with the assistance of drops of liquid 260 (FIG. 4B), microchips 200 are selectively separated from support substrate 401. Support substrate 401 and the remaining microchips 200 are then removed as illustrated in FIG. 4C.

To selectively separate microchips 200 from support substrate 401, a light bonding between support substrate 401 and microchips 200 may be provided, so that only the microchips 200 aligned with the corresponding connection areas of transfer substrate 250 are torn off during the removal of support substrate 401, under the effect of the capillary force exerted by liquid drops 260 or under the effect of the direct bonding force between the microchip and the transfer substrate. As an example, microchips 200 are bonded to support substrate 401 by means of a polymer of type C4F8, TEFLON, or OPTOOL DSX, or by any other adhesive providing a bonding energy between microchips 200 and support substrate 401 smaller than the bonding energy between microchips 200 and transfer substrate 250.

As a variation, in the case where support substrate 401 is transparent, the bonding of microchips 200 to support substrate 401 may be achieved with a resin capable of being degraded by an ultraviolet radiation, for example, a resin of BREWER 305 type. A local laser illumination of the resin may then be performed through substrate 401, to selectively separate part of microchips 200.

In the case where support substrate 401 is the growth substrate of LEDs 110, the latter may have a relatively strong adherence to microchips 200. In this case, a method of selective separation by means of a local laser beam projected through substrate 401, for example, a method of the type described in patent application U.S. Pat. No. 6,071,795, may be used. For example, in the case of a sapphire growth substrate 401 and of gallium nitride LEDs, a 458-nm laser may be used, with an optical power in the range from 10 mW/mm2 to 10 W/mm2 and an exposure time in the range from 1 second to 1 minute for each chip to be separated. After the exposure to the laser, liquid gallium is present at the interface between the LED and the sapphire. The microchip then is held by capillary on substrate 401, until it is transferred onto substrate 250.

It should be noted that to increase the bonding force between microchips 200 and transfer substrate 250, and thus ease the separation from support substrate 401, an anneal aiming at increasing the bonding energy between the microchips and the transfer substrate, for example, at a temperature in the range from 150 to 250° C., may be performed before removing substrate 401 (FIG. 4C).

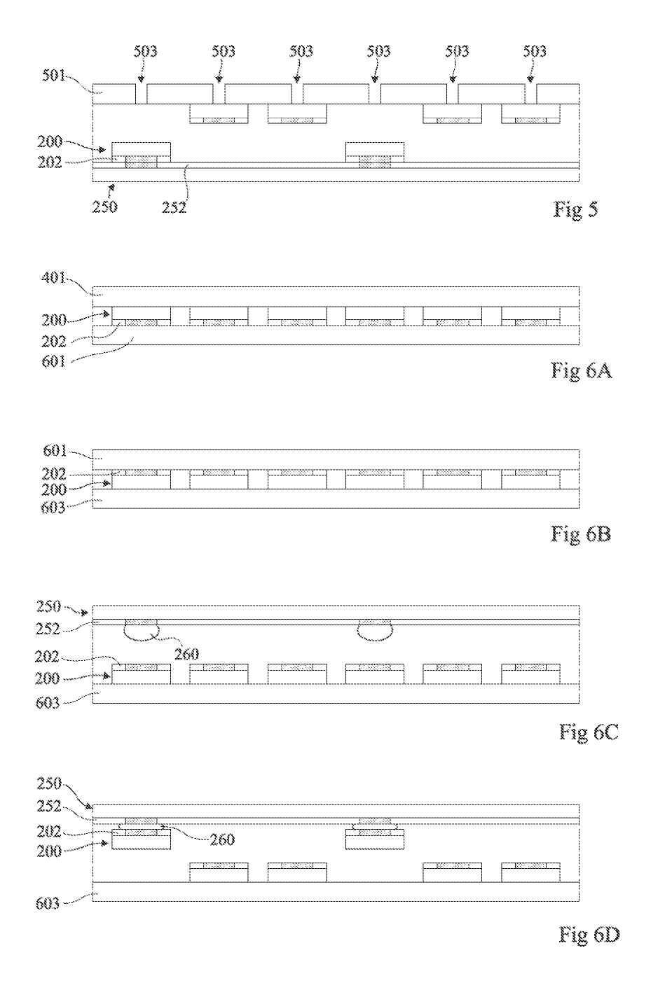

FIG. 5 is a cross-section view illustrating an alternative embodiment of the method of FIGS. 4A to 4C.

The method of FIG. 5 differs from the method of FIGS. 4A to 4C mainly in that, in the method of FIG. 5, support substrate 401 of FIGS. 4A to 4C is replaced with a support substrate 501 comprising at least one through opening 503 opposite each microchip 200. The provision of through openings 503 enables to ease the selective separation of microchips 200 when they are transferred onto substrate 250. As an example, microchips 200 are maintained bonded to substrate 501 by an adhesive, and a compressed air flow is locally injected into the openings 503 located opposite the microchips to be detached, to obtain their separation. As a variation, microneedles may be used to selectively push the microchips to be detached through the corresponding openings 503. As a variation, the microchips are maintained bonded to substrate 501 by sucking in through openings 503, after which the sucking is locally interrupted opposite the microchips to be detached, to obtain their separation.

FIGS. 6A to 6D are cross-section views illustrating steps of another embodiment of an emissive LED display device manufacturing method.

FIG. 6A illustrates a step during which, after microchips 200 have been formed on a first support substrate 401 identically or similarly to what has been previously described in relation with FIG. 4A, microchips 200 are transferred from substrate 401 onto a second support substrate 601, with no pitch change. For this purpose, microchips 200 are arranged on substrate 601, using substrate 401 as a handle. Microchips 200 are placed into contact, by their connection surfaces, that is, their surfaces opposite to LEDs 110, with a surface of substrate 601. A temporary bonding by means of an adhesive layer may be provided between the connection surface of the microchips and substrate 601. As a variation, microchips 601 are simply laid on the upper surface of substrate 601. Initial support substrate 401 is then removed.

FIG. 6B illustrates a step subsequent to the removal of initial support substrate 401, during which microchips 200 are transferred from second support substrate 601 to the upper surface of a third support substrate 603, still keeping the initial pitch. In the case where microchips 200 are bonded to temporary support substrate 601 by an adhesive layer, the microchips may be placed on the upper surface of substrate 603, using substrate 601 as a handle. In the case where microchips 200 are simply laid on the upper surface of temporary support substrate 601, substrate 603 may be laid on the upper surface of microchips 200, that is, on the side of LED 110, after which the assembly comprising substrate 601, microchips 200, and substrate 603 is flipped so that microchips 200 are on the upper surface side of substrate 603. Temporary support substrate 601 is then removed.

FIG. 6C illustrates a step subsequent to the removal of substrate 601. At this stage, microchips 200 are simply laid (and not bonded) on the upper surface of support substrate 603, the connection surfaces of the microchips facing upwards, that is, opposite substrate 603.

The transfer substrate 250 having microchips 200 desired to be affixed thereon is then positioned above substrate 603 and microchips 200, with its connection surface facing the connection surfaces of the microchips. Previously, drops of liquid 260 have been placed on the electric connection areas of the transfer substrate 250. Microchips 200, laid on support substrate 603, are brought opposite the corresponding receive areas of transfer substrate 250, after which the electric connection areas of microchips 200 are placed into contact with the drops of liquid 260 arranged on the corresponding electric connection areas of the transfer substrate.

The capillary restoring force exerted by the drops of liquid 260 on the hydrophilic electric connection areas attracts microchips 200 (which are free to move with respect to substrate 603 due to the lack of bonding between the microchips and the substrate) and results in accurately self-aligning the connection areas of each microchip with the corresponding electric connection areas of the transfer substrate.

Microchips 200 are then affixed to transfer substrate 250 by direction bonding. For this purpose, a pressure may for example be applied to microchips 200 to drain off the drops of liquid 260, or liquid 260 may be evaporated, to obtain a direct bonding between the microchips and the transfer substrate.

Transfer substrate 603 and the remaining microchips 200 may be removed as illustrated in FIG. 6D.

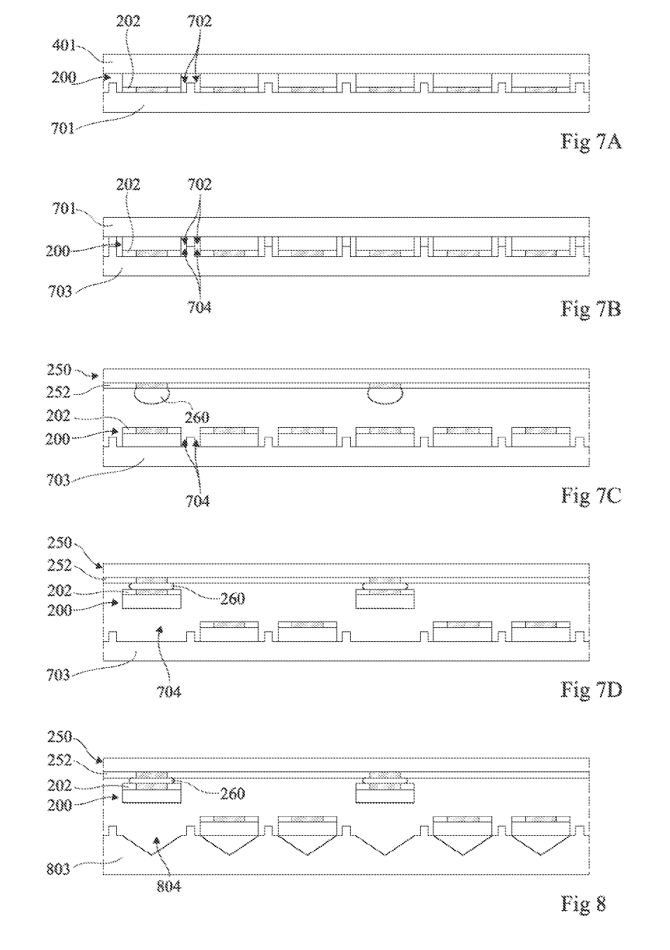

FIGS. 7A to 7D are cross-section views illustrating steps of another embodiment of a method of manufacturing an emissive LED display device.

The method of FIGS. 7A to 7D is similar to the method of FIGS. 6A to 6D, and differs from the method of FIGS. 6A to 6D mainly in that, in the method of FIGS. 7A to 7D, support substrates 601 and 603 of the method of FIGS. 6A to 6D are replaced with substrates 701 and 703, respectively. Substrates 701 and 703 differ from substrates 601 and 603 in that they each comprise, on the side of their surface intended to receive microchips 200, cavities 702 (for substrate 701), respectively 704 (for substrate 703), intended to receive microchips 200.

More particularly, when microchips 200 are transferred from initial support substrate 401 onto substrate 701 (FIG. 7A), each microchip 200 is arranged in a cavity 702 of substrate 701, and is separated from the other microchips 200 transferred onto substrate 701 by the lateral walls of cavity 702. In other words, the pitch of cavities 702 of substrate 701 is substantially identical to the pitch of microchips 200 on substrate 401. Similarly to what has been described in relation with FIGS. 6A to 6D, microchips 200 may be affixed to temporary support substrate 701 by an adhesive layer, or may be simply laid on substrate 701. Initial support substrate 401 is then removed.

Further, when microchips 200 are transferred from temporary support substrate 701 onto support substrate 703 (FIG. 7B), each microchip 200 is arranged in a cavity 704 of substrate 703, and is separated from the other microchips 200 by the lateral walls of cavity 704. In other words, the pitch of cavities 704 of substrate 703 is substantially identical to the pitch of microchips 200 on initial substrate 401. Similarly to what has been described in relation with FIGS. 6A to 6D, microchips 200 are simply laid on support substrate 703.

The other steps of the method are identical or similar to what has been previously described in relation with FIGS. 6A to 6D.

An advantage of the variation of FIGS. 7A to 7D is to ease the handling of support substrate 701 and/or 703 once the latter have been loaded with microchips 200, due to the lateral holding of the microchips obtained by the provision of cavities 702, 704.

FIG. 8 is a cross-section view illustrating an alternative embodiment of the method of FIGS. 7A to 7D.

FIG. 8 more particularly illustrates a final step of the method, corresponding to the step of FIG. 7D.

In the variation of FIG. 8, support substrate 703 of the method of FIGS. 7A to 7D is replaced with a support substrate 803. Substrate 803 comprises cavities 804 for holding microchips 200, arranged with a pitch substantially equal to the pitch of the microchips on initial support substrate 401. Substrate 803 of the method of FIG. 8 differs from substrate 703 of the method of FIGS. 7A to 7D mainly in that the bottom of each cavity 804 of substrate 803 is non-planar. In other words, conversely to substrate 703 where the entire surface of a microchip 200 opposite to the connection surface of the microchip is in contact with the bottom of a cavity 704 of the substrate, in the example of FIG. 8, for each microchip 200, a portion only of the surface of the microchip opposite to its connection surface is in contact with the bottom of cavity 804 having the microchip arranged therein. This enables to prevent an unwanted bonding of microchips 200 to the bottom of the cavities of substrate 803, and thus to ease the sampling of the microchips by transfer substrate 250 during the self-assembly step.

As an example, the bottom of each cavity 804 of substrate 803 may have a hollow shape, for example, the shape of a groove portion with a triangular cross-section. More generally, any other non-planar shape capable of obtaining the desired anti-bonding effect may be used, for example, a bulged shape.

Specific embodiments have been described. Various alterations, modifications, and improvements will occur to those skilled in the art. In particular, the described embodiments are not limited to the specific examples of dimensions and of materials mentioned in the description.

It should further be understood that the methods of FIGS. 4A to 4C, 6A to 6D, 7A to 7D, and 8 may be implemented with microchips 300 and/or with a transfer substrate 350 of the type described in relation with FIG. 3.

Further, although only examples of implementation where the microchips transferred onto the transfer substrate each comprise a LED and a circuit for controlling the LED have been described, the described embodiments are not limited to this specific case. As a variation, each microchip may comprise a plurality of LEDs and an active circuit for controlling the plurality of LEDs. Further, in another variation, each microchip may comprise one or a plurality of LEDs only, with no control circuit, the LED(s) of the microchip being then controlled by circuits external to the microchip, for example arranged at the periphery of the transfer substrate.

Further, the described embodiments are not limited to the shown examples where each microchip comprises four electric connection areas.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method of manufacturing an emissive LED display device, comprising the steps of:
a) forming a plurality of chips, each comprising at least one LED and, on a connection surface of the chip, a plurality of hydrophilic electric connection areas and a hydrophobic area, each electric connection area of the chip being surrounded and separated from the other electric connection areas of the chip by the hydrophobic area;
b) forming a transfer substrate comprising, for each chip, on a connection surface of the transfer substrate, a plurality of hydrophilic electric connection areas intended to be respectively connected to the electric connection areas of the chip, and a hydrophobic area, each electric connection area of the transfer substrate being surrounded and separated from the other electric connection areas of the transfer substrate by the hydrophobic area;
c) arranging a drop of a liquid on each electric connection area of the transfer substrate and/or on each electric connection area of each chip; and
d) affixing the chips to the transfer substrate by direct bonding to electrically connect the electronic connection areas of each chip to the corresponding electric connection areas of the transfer substrate, using the capillary restoring force of the drops to align the electric connection areas of the chips with the corresponding electric connection areas of the transfer substrate.

2. The method of claim 1, wherein the electric connection areas of the chips and of the transfer substrate are made of metal, and wherein the hydrophobic areas of the chips and of the transfer substrate are made of a hydrophobic polymer.

3. The method of claim 1, wherein the electric connection areas of the chips and of the transfer substrate are made of a material forming a drop contact angle smaller than 10° with the liquid, and wherein the hydrophobic areas of the chips and of the transfer substrate are made of a material forming a drop contact angle greater than 20° with the liquid.

4. The method of claim 1, wherein:
in each chip, the connection surface of the chip is planar, that is, the electric connection areas of the chip are flush with the external surface of the hydrophobic area; and/or
the connection surface of the transfer substrate is planar, that is, the electric connection areas of the transfer substrate are flush with the external surface of the hydrophobic area.

5. The method of claim 1, wherein:
in each chip, the electric connection areas of the chip form raised areas protruding from the connection surface of the chip; and/or
the electric connection areas of the transfer substrate form raised areas protruding from the connection surface of the transfer substrate.

6. The method of claim 1, wherein:
at the end of step a), the chips are arranged on a support substrate with a pitch between chips smaller than the pitch between chips of the final display device; and
at step d), a plurality of chips are selectively separated from the support substrate at the pitch of the final display device and affixed to the transfer substrate at this same pitch.

7. The method of claim 6, wherein the selective separation of the chips is formed by means of a local laser beam projected from the surface of the support substrate opposite to the chips.

8. The method of claim 6, wherein the support substrate comprises one or a plurality of through openings opposite each chip, the selective separation of the chips being performed via these openings.

9. The method of claim 6, wherein:
at the end of step a), the chips are only laid, with no bonding, on the support substrate; and
at step d), the transfer substrate is brought above the chips, with its connection surface facing the connection surfaces of the chips, and laid on the chips to simultaneously sample a plurality of chips at the pitch of the final display device.

10. The method of claim 9, wherein the support substrate comprises cavities having the chips arranged therein so that the chips are laterally held by the cavity walls.

11. The method of claim 10, wherein the bottom of each cavity of the support substrate is non-planar.

12. The method of claim 1, wherein each chip comprises a stack of a LED and of an active circuit for controlling the LED.

13. An emissive LED display device, comprising:
a plurality of chips, each comprising at least one LED and, on a connection surface of the chip, a plurality of hydrophilic electric connection areas and a hydrophobic area, each electric connection area of the chip being surrounded and separated from the other electric connection areas of the chip by the hydrophobic area; and
a transfer substrate comprising, for each chip, on a connection surface of the transfer substrate, a plurality of hydrophilic electric connection areas respectively connected to the electric connection areas of the chip, and a hydrophobic area, each electric connection area of the transfer substrate being surrounded and separated from the other electric connection areas of the transfer substrate by the hydrophobic area,
wherein the chips (200; 300) are affixed to the transfer substrate by direct bonding to electrically connect the electronic connection areas of each chip to the corresponding electric connection areas of the transfer substrate.
